(19) United States
(12) Patent Application Publication
(10) Pub. No.: US 2017/0271419 A1
(43) Pub. Date: Sep. 21, 2017

(54) POLYMER LIGHT-EMITTING DIODE STRUCTURE, RELATED DISPLAY SUBSTRATE AND DISPLAY APPARATUS, AND FABRICATION METHOD THEREOF

(71) Applicant: BOE TECHNOLOGY GROUP CO., LTD, Beijing (CN)

(72) Inventors: YING CUI, Beijing (CN); CHUNJING HU, Beijing (CN)

(73) Assignee: BOE TECHNOLOGY GROUP CO., LTD., Beijing (CN)

(21) Appl. No.: 15/305,463

(22) PCT Filed: Nov. 12, 2015
(86) PCT No.: PCT/CN2015/094403

§ 371 Date: Oct. 20, 2016

(51) Int. Cl. H01L 27/32; H01L 51/50; H01L 51/56; H01L 51/52

(52) U.S. Cl. CPC H01L 27/3246; H01L 51/5221; H01L 51/5012; H01L 51/5206; H01L 27/3258; H01L 27/3262; H01L 51/56; H01L 2251/558; H01L 2251/301

(57) ABSTRACT

The present disclosure provides a polymer light-emitting diode (PLED) structure. The structure includes a substrate; an anode layer on the substrate; and a pixel defining layer for defining a display region with a plurality of pixels. The structure also includes a light-emitting layer in subpixels of each pixel for illuminating light of a color; a subpixel barrier layer substantially positioned between the pixel defining layer and a cathode layer for covering a peripheral portion of the light-emitting layer and exposing a center portion of the light-emitting layer, an orthogonal projection of the subpixel barrier layer on the substrate overlapping with a portion of an orthogonal projection of the peripheral region of the light-emitting layer on the substrate; and the cathode layer contacting the center portion of the light-emitting layer.

### FIELD OF THE INVENTION

The present invention generally relates to the display technologies and, more particularly, relates to a polymer light-emitting diode structure, related display substrates and display apparatus, and related fabrication method thereof.

### BACKGROUND

Inkjet-printed light-emitting devices, e.g., polymer light-emitting diode (PLED) display products are easy to produce and are cost-effective. The inkjet printing technologies to fabricate PLED display products are easy to implement and can be used to fabricate large-sized display products. As the high-performance polymers and thin film fabrication methods advance, PLED display products have been widely adopted.

In inkjet printing technologies, hole transport layer (HTL) material, such as poly(3,4-ethylenedioxythiophene):poly(4-styrenesulfonate) (PEDOT:PSS), and conductive colorant solution or colorant ink containing the chemicals for emitting light of different colors, such as red, green, and blue, are often printed on a display substrate using nozzles. The nozzles eject the solution in micron-level droplets onto a patterned indium tin oxide (ITO) layer, often the anode layer, to fill pre-defined subpixel regions. The solution or printed colorant link layers are then dried to form subpixels, i.e., subpixel thin films, of different colors arranged in an array on the display substrate. Using various inkjet printing technologies, less of the expensive light-emitting materials are used to form the display substrate. Also, by using more nozzles, e.g., 128 or 256 nozzles, for printing, the time needed for thin film or subpixel fabrication can be greatly reduced.

However, in conventional inkjet printing processes, when the printed colorant ink layers are being dried to form the subpixel thin films, subpixel thin film in a subpixel region often would have a thicker peripheral portion and a thinner center portion. This is often referred to as the coffee ring formation due to outward deflection of momentum in the printed colorant ink layer during the drying process. Specifically, the drying of the colorant ink layer includes evaporation of solvent, largely on the peripheral portion of the colorant ink layer. This evaporation often causes the printed colorant ink to move from the center portion of the colorant ink layer. The evaporation also causes the solute to migrate to the peripheral portion and accumulate or segregate on the peripheral portion to form a thicker peripheral portion and a thinner center. As a result, the formed subpixel thin films may not have a uniform thickness. A thicker peripheral portion, with more light-emitting solute accumulated, may emit light of a higher intensity than the thinner center portion. In addition, the electric current flowing through the peripheral portion may be higher, causing the electric current flowing through the thin film to be non-uniformed. The service time and the lighting quality of the subpixels may be adversely affected by the coffee ring formation.

### BRIEF SUMMARY OF THE DISCLOSURE

The present disclosure provides an insulating layer on the pixel defining layer surrounding the printed colorant ink layers to insulate the non-uniformed peripheral portion of the printed colorant ink layers from the cathode layer and prevent the non-uniformed peripheral portion of the subpixel thin film from emitting light. Embodiments of the present disclosure thus improve the uniformity of the subpixel thin films formed in the subpixel regions and the service time of the formed subpixels.

One aspect of the present disclosure includes a polymer light-emitting diode (PLED) structure. The PLED structure includes a substrate; an anode layer on the substrate; and a pixel defining layer for defining a display region with a plurality of pixels. The PLED structure also includes a light-emitting layer in subpixels of each pixel for illuminating light of a color; a subpixel barrier layer substantially positioned between the pixel defining layer and a cathode layer for covering a peripheral portion of the light-emitting layer and exposing a center portion of the light-emitting layer, an orthogonal projection of the subpixel barrier layer on the substrate overlapping with a portion of an orthogonal projection of the peripheral region of the light-emitting layer on the substrate; and the cathode layer contacting the center portion of the light-emitting layer.

Optionally, in operation, the subpixel barrier layer provides electrical insulation between the light-emitting layer and the cathode layer.

Optionally, in operation, the subpixel barrier layer blocks light exiting from the peripheral portion of the light-emitting layer.

Optionally, the peripheral portion of the light-emitting layer covered by the subpixel barrier layer has a thickness greater than a thickness of the center portion of the light-emitting layer for at least 3%.

Optionally, the subpixel barrier layer contacts the sidewall of the subpixel pit and provides adhesion between the pixel defining layer and the cathode layer.

Optionally, a thickness of the subpixel barrier layer is at least partially dependent on a width of the peripheral portion of the light-emitting layer.

Optionally, the thickness of the subpixel barrier layer is substantially equal to a thickness of the light-emitting layer.

Optionally, the subpixel barrier layer covers the peripheral portion of the light-emitting layer and the sidewall of the pixel defining layer.

Optionally, the cathode layer covers the center portion of the light-emitting layer, the subpixel barrier layer, and the pixel defining layer.

Optionally, the subpixel barrier layer is made of one or more of SiOₓ, SiNₓ and SiOₓN_{y}.

Optionally, the PLED structure further includes a substrate with a thin-film transistor (TFT) array, a gate insulating layer, and a planarization layer.

Another aspect of the present disclosure provides a method for forming a polymer light-emitting diode (PLED) structure for a display substrate, including: providing a substrate with a thin-film transistor (TFT) array and an anode layer; forming a pixel defining layer with subpixel pits corresponding to pixels of the display substrate, a bottom of each pit exposing a portion of the anode layer; and forming a light-emitting layer in each subpixel pit, each light-emitting layer filling up a portion of each pit, contacting a sidewall of the pit and an exposed portion of the anode layer. The method also includes forming a patterned subpixel barrier layer to cover at least a peripheral portion of the light-emitting layer and to expose a center portion of the light-emitting layer; and forming a cathode layer to cover at least the center portion of the light-emitting layer and form contact with the center portion of the light-emitting layer.

Optionally, in operation, the subpixel barrier layer provides electrical insulation between the peripheral portion of the light-emitting layer and the cathode layer so that the peripheral portion of the light-emitting layer does not emit light.

Optionally, in operation, the subpixel barrier layer blocks light exiting from the peripheral portion of the light-emitting layer.

Optionally, in operation, light emitted by the light-emitting layer has substantial uniformity.

Optionally, the peripheral portion of the light-emitting layer covered by the subpixel barrier layer has a thickness greater than a thickness of the center portion of the light-emitting layer by at least 3%.

Optionally, a thickness of the subpixel barrier layer is at least partially dependent on a width of the peripheral portion of the light-emitting layer.

Optionally, an orthogonal projection of the subpixel barrier layer on the substrate overlaps with a portion of an orthogonal projection of the peripheral portion of the light-emitting layer on the substrate.

Optionally, the patterned subpixel barrier layer is formed by: forming a subpixel barrier film to cover at least the light-emitting layer by vapor deposition; and patterning the subpixel barrier film to form the subpixel barrier layer, the subpixel barrier layer covering at least the peripheral portion of the light-emitting layer and exposing the center portion of the light-emitting layer.

Optionally, the subpixel barrier layer is made of one or more of SiOₓ, SiNₓ and SiOₓN_{y}.

Another aspect of the present disclosure provides a display substrate, incorporating a plurality of the disclosed PLED structures.

Another aspect of the present disclosure provides a display apparatus, incorporating the disclosed display substrate.

Other aspects of the present disclosure can be understood by those skilled in the art in light of the description, the claims, and the drawings of the present disclosure.

### BRIEF DESCRIPTION OF THE DRAWINGS

The following drawings are merely examples for illustrative purposes according to various disclosed embodiments and are not intended to limit the scope of the present disclosure.

FIG. 1 illustrates a cross-sectional view of an exemplary PLED structure according to the embodiments of the present disclosure; and

FIG. 2 illustrates an exemplary process flow for fabricating a PLED structure according to the embodiments of the present disclosure.

### DETAILED DESCRIPTION

For those skilled in the art to better understand the technical solution of the invention, reference will now be made in detail to exemplary embodiments of the invention, which are illustrated in the accompanying drawings. Wherever possible, the same reference numbers will be used throughout the drawings to refer to the same or like parts.

One aspect of the present disclosure provides a PLED structure.

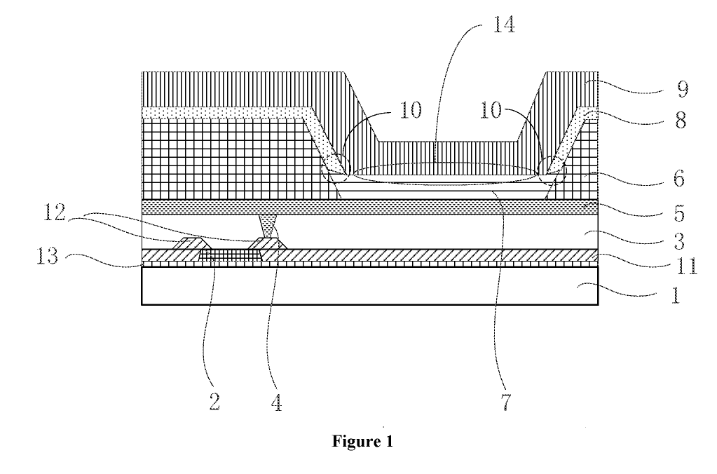

FIG. 1 illustrates the cross-sectional view of an exemplary PLED structure. The PLED structure may include a substrate 1, an isolation layer 13, a thin-film transistor (TFT) layer 2, a gate insulating layer 11, a planarization layer 3, a via hole 4, an anode layer 5, a pixel defining layer 6, a light-emitting layer 7, a subpixel barrier layer 8, and a cathode layer 9. For illustrative purposes, FIG. 1 only shows a source and a drain, indicated by the elements 12, of one TFT in the TFT layer 2. The pixel defining layer 6 may be used to define a display region with a plurality of pixels and may also be referred as a patterned bank layer.

The substrate 1 may be made of any suitable material such as silicon or glass. The isolation layer 13 may be formed on the substrate 1 and may be made of any suitable material capable of providing electrical insulation between the TFT layer 2 and the substrate 1. For example, the isolation layer 13 may be made of SiO₂, SiN, and so on. The TFT layer 2, containing a plurality of TFTs, may be formed on the isolation layer 13. The gate insulating layer 11 may be formed to cover the gates of the TFTs and expose at least a drain and a source 12. The gate insulating layer 11 may prevent the gates of the TFTs from contacting other parts of the PLED structure. The gate insulating layer 11 may be made of any suitable material capable of providing electrical insulation and protection of the gates, such as SiO₂ and/or SiN.

A planarization layer 3 may be formed on the gate insulating layer 11 to cover the source and the drain 12 and the TFT layer 2. The planarization layer 3 may be of any suitable material capable of providing electrical insulation and a fabrication base, e.g., flatness, for the anode layer 5, such as SiO₂ and/or SiN. The anode layer 5 may be formed on the planarization layer 3. The anode layer 5 may be made of any suitable material with substantial transparency such as indium tin oxide (ITO). One of the drain and source 12 may be connected to the anode layer 5 through the via hole 4, which may be filled with suitable metals such as copper and/or aluminum.

The pixel defining layer 6 (PDL), also referred as a patterned bank layer, may be formed on the anode layer 5. The pixel defining layer 6 may be patterned to form subpixel placing regions, e.g., subpixel pits, corresponding to the subsequently formed subpixels. The pixel defining layer 6 may be patterned through any suitable patterning process, e.g., a photolithography process and a follow-up etching process, to remove certain portions of the pixel defining layer 6 and form subpixel pits. Each subpixel pit may expose the surface of the anode layer 5 at the bottom of the subpixel pits. The sidewall of a subpixel pit may or may not be perpendicular to the surface of the anode layer 5.

In one embodiment, the sidewall of a subpixel pit may not be perpendicular to the surface of the anode layer 5 such that the cross-section of the subpixel pit may have a smaller width at the bottom and a greater width at the top. The subpixel pits may be partially filled with colorant ink of different colors, such as red, green, and blue, ejected from nozzles. The subpixel pits corresponding to different colors may be arranged in an array so that subpixels of different colors may be formed. Pixels may further be formed by multiple subpixels. The pixel defining layer 6 may be made of any suitable material capable of providing electrical insulation between subpixels and defining the pattern of the subpixels. For example, the pixel defining layer 6 may be made of polymer.

The light-emitting layer 7, which may be a conductive colorant ink layer of a certain color, e.g., red, green, or blue, inkjet printed or ejected by a nozzle, may be formed on the anode layer 5 to contact the anode layer 5 and a portion of the sidewall of the pixel defining layer 6. The conductive colorant ink layer may be a solution containing light-emitting organic materials or chemicals, such as dyes. The colorant ink layer may be of liquid form when ejected by the nozzle and may be dried to form a subpixel thin film after a drying process. The subpixel thin film may emit light of a certain color, e.g., red, green, or blue, when in operation. The subpixel thin film may be a subpixel. In this disclosure, the formed subpixel thin film or the light-emitting layer 7 may be referred as a subpixel film. Because the solute of the solution contains light-emitting materials capable of emitting light of a certain color in operation, the thickness of the subpixel film may correspond to the concentration of solute in the solution and may be adjusted to ensure the light emitted by the subpixel has desired intensity or brightness levels. For example, for the same amount of solute contained in subpixel film, a lower concentration of the solute may correspond to a thicker subpixel film, and a higher concentration of the solute may correspond to a thinner subpixel film. Also, for a certain concentration of solute, a thicker subpixel film may contain more solute and a thinner subpixel film may contain less solute. In one embodiment, the subpixel film may be a few hundred nanometers thick.

For illustrative purposes, FIG. 1 only shows a single light-emitting layer 7. In practice, a HTL may be formed between the anode layer 5 and the light-emitting layer 7. The HTL may facilitate hole transportation from the anode layer 5 to the light-emitting layer 7 in operation. Optionally, in practice, an electron transport layer (ETL) may be formed between the cathode layer 9 and the light-emitting layer 7 to facilitate transportation of electrons from the cathode layer 9 to the light-emitting layer 7.

The subpixel barrier layer 8 may be formed on the pixel defining layer 6 to cover the peripheral portion 10 of each light-emitting layer 7. The cathode layer 9 may be formed to cover the light-emitting layer 7 and the subpixel barrier layer 8. In operation, the subpixel barrier layer 8 may provide electrical insulation between the peripheral portion of the light-emitting layer 7 and the cathode layer 9, and may block the light exiting from the peripheral portion of the light-emitting layer 7. The thickness of the subpixel barrier layer 8 may be at least partially dependent on the width of the peripheral portion 10 the light-emitting layer 7. The subpixel barrier layer 8 may have a desired thickness to provide sufficient electrical insulation between the peripheral portion 10 of the light-emitting layer 7 and the cathode layer 9. Meanwhile, the subpixel insulating 8 should not be overly thick so that no void can be formed between the cathode layer 9 and the light-emitting layer 7. The subpixel barrier layer 8 may only cover the peripheral portion 10 of the light-emitting layer 7, which has a different thickness than the center portion 14 of the light-emitting layer 7. The subpixel barrier layer 8 may not be required to cover the entire surface of the pixel defining layer 6. The center portion 14 may refer to the regions between the peripheral portion 10 of the light-emitting layer 7 and the geometrical center of the light-emitting layer 7. The center portion 14 of the light-emitting layer 7 is circled by a solid line in FIG. 14. An orthogonal projection of the subpixel barrier layer 8 on the substrate overlaps with a portion of an orthogonal projection of the peripheral portion 10 of the light-emitting layer 7 on the substrate.

The subpixel barrier layer 8 may improve the adhesion between the pixel defining layer 6 and the cathode layer 9. The subpixel barrier layer 8 may be made of any suitable insulating material such as bisphenol A, polypropylene, SiOₓ, SiNₓ, and/or SiOₓN_{y}. The cathode layer 9 may be made of any suitable metal or metal alloy such as Al and/or MgAl. For illustrative purposes, in one embodiment, the cathode layer 9 shown in FIG. 1 may cover the pixel defining layer 6, the light-emitting layer 7, and the subpixel barrier layer 8. In practice, the cathode layer 9 may only contact the exposed portions of the light-emitting layer 7. The specific surface coverage of the cathode layer 9 may be subject to different applications and should not be limited by the embodiments herein.

Because of the coffee ring formation, the peripheral portion 10 of a light-emitting layer 7, i.e., a dried colorant ink layer, may have a greater thickness than the center portion 14 of the light-emitting layer 7. For viewing simplicity, the greater thickness of the peripheral portion 10 may be illustrated by an increase in the slope of the surface of the light-emitting layer 7, marked in dashed line circles. That is, more solutes may be contained in the peripheral portion 10 of a light-emitting layer 7, which may emit light of a higher intensity than portions of the light-emitting layer 7 with a lower concentration of solutes in operation. This may cause the light emitted by the subpixel to have non-uniformed brightness or intensity levels. The subpixel barrier layer 8 may cover the peripheral portion 10 of the light-emitting layer 7 to insulate the peripheral portion 10 of the light-emitting layer 7 from the cathode layer 9. Thus, when in operation, no electric current may flow through the peripheral portion 10 of the light-emitting layer 7 and no light may be emitted by the peripheral portion 10 of the light-emitting layer 7. Because the thickness of the light-emitting layer 7 at the center portion 14 is substantially the same, the amount of solutes contained in the center portion 14 may be substantially the same. Thus, light may only be emitted from the center portion 14 of the light-emitting layer 7 and may have a more uniformed intensity level. In other words, light emitted by the subpixel, corresponding to the light-emitting layer 7, may have improved uniform intensity. Meanwhile, because electric current may only flow through the center portion 14 of the light-emitting layer 7, the intensity of the electric current may be more uniformed through the subpixel. Thus, the subpixel, corresponding to the light-emitting layer 7, may have improved service time.

It should be noted that, the thickness of the subpixel barrier layer 8 may be adjusted according to the width of the non-uniformed peripheral portion 10 of the light-emitting layer 7 to at least substantially cover the peripheral portion 10 of the light-emitting layer 7. For example, the peripheral portion 10 of the light-emitting layer 7 may include a wider or a narrower area, depending on different printing processes and drying processes. In one embodiment, the subpixel barrier layer 8 may fully cover the peripheral portion 10 of the light-emitting layer 7. The specific thickness of the subpixel barrier layer 8 may be determined according to the specific area of the non-uniformed peripheral portion 10 and should not be limited by the embodiments of the present disclosure. It should be noted that, the subpixel barrier layer 8 may be sufficient thick to provide electrical insulation between the peripheral portion 10 of the light-emitting layer 7 so that the peripheral portion 10 would not emit light in operation. Meanwhile, the subpixel barrier layer 8 should not be overly thick to cause a void between the light-emitting layer 7 and the cathode layer 9. The thickness of the subpixel barrier layer 8 should also be adjusted to a desired range so that a desired area of the center portion 14 of the light-emitting layer 7 can be exposed for sufficient light to be emitted by the light-emitting layer 7. The specific thickness of the subpixel barrier layer 8 may be subjected to the materials of the subpixel barrier layer 8 and the light-emitting layer 7 and should not be limited to a fixed value. In one embodiment, the subpixel barrier layer 8 may be the same as the width of peripheral portions 10 of the light-emitting layer 7. The subpixel barrier layer 8 may be formed by vapor deposition.

In some embodiments, the subpixel barrier layer 8 may be formed when the thickness of the peripheral portion of the light-emitting layer 7 is at least 3% greater than the thickness of the center portion of the light-emitting layer 7. The thickness of the subpixel barrier layer 8 may be substantially the same as or comparable to the thickness of the light-emitting layer 7.

In operation, a potential may be applied between the cathode layer 9 and the anode layer 5 by the TFT layer 2. Electrons may enter the light-emitting layer 7 from the cathode layer 9 and the holes may enter the light-emitting layer 7 from the anode layer 5. Electrons and holes may recombine in the light-emitting layer 7. Because the solute contained in the light-emitting layer 7 can emit light of a certain color under electrical field, the light-emitting layer 7 may emit light of a certain color, e.g., red, green, or blue. The intensity of the light emitted by the light-emitting layer 7 may be directly related to the concentration or amount of solutes contained in a certain volume of the light-emitting layer 7 and the center portion 14 exposed by the subpixel barrier layer 8. The peripheral portion 10 of the light-emitting layer 7 may have a greater thickness than the center portion 14 of the light-emitting layer 7 due to the coffee ring formation, so that the peripheral portion 10 may contain a greater amount of solutes for emitting light.

With the subpixel barrier layer 8 covering the peripheral portion 10 of the light-emitting layer 7, the peripheral portion 10 of the light-emitting layer 7 may be electrically insulated from the cathode layer 9, and no or little electric current may be formed in the peripheral portion 10 of the light-emitting layer 7. No light may be emitted from the peripheral portion 10 of the light-emitting layer 7. That is, in operation, only the center portion 14 of the light-emitting layer 7 may emit light, and the peripheral portion 10 of the light-emitting layer 7 would not emit light. Because the center portion 14 of the light-emitting layer 7 may have a substantially uniformed thickness, the light emitted from the center portion 14 of the light-emitting layer 7 may have a uniformed intensity level. In addition, because the electric current flowing through the center portion 14 of the light-emitting layer 7 may have improved uniformity, the service time of the subpixel can be improved.

Another aspect of the present disclosure provides a method for forming the PLED.

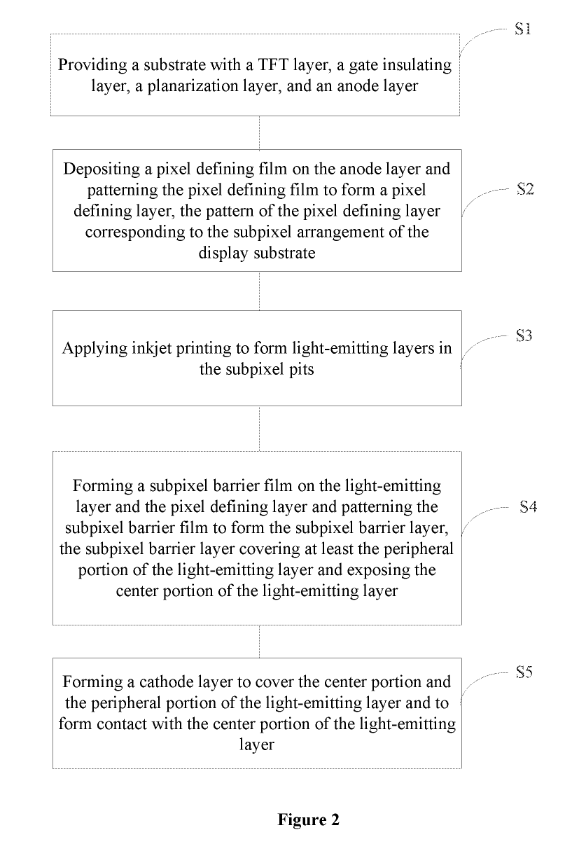

FIG. 2 illustrates the process flow of an exemplary fabrication process for forming the PLED. The process may include steps S1 to S5.

In step S1, a substrate with a TFT layer, a gate insulating layer, a planarization layer, and an anode layer is provided.

As shown in FIGS. 1 and 2, the substrate 1 with the TFT layer 2, the gate insulating layer 11, the planarization layer 3, and the anode layer 5 may be provided. The TFT layer 2, containing a plurality of TFTs, may be formed on the substrate 1. The gate insulating 11 may be formed to cover the gates of the TFTs and expose at least a drain and a source 12. The gate insulating layer 11 may prevent the gates of the TFTs from contacting other parts of the PLED structure. The gate insulating layer 11 may be made of any suitable material capable of providing electrical insulation and protection of the gates, such as SiO₂ and SiN.

A planarization layer 3 may be formed on the gate insulating layer 11 to cover the source and the drain 12 and the TFT layer 2. The planarization layer 3 may be made of any suitable material capable of providing electrical insulation and a fabrication base, e.g., flatness, for the anode layer 5. The anode layer 5 may be formed on the planarization layer 3. The anode layer 5 may be made of any suitable material with substantial transparency such as ITO. One of the drain and source 12 may be connected to the anode layer 5 through a via hole 4, which may be filled with suitable metals such as copper and/or aluminum.

Optionally, an isolation layer 13 may be formed between the substrate 1 and the TFT layer 2. The isolation layer 13 may be made of any suitable material capable of providing electrical isolation between the TFT layer 2 and the substrate 1.

In step S2, a pixel defining film is deposited on the anode layer 5 and patterned to form a pixel defining layer. The pattern of the pixel defining layer corresponds to the subpixel arrangement of the display substrate.

As shown in FIGS. 1 and 2, a pixel defining film, made of any suitable insulating materials such as SiO₂ and/or SiN, may be deposited on the anode layer 5. The pixel defining film may be formed by any suitable deposition methods such as vapor deposition. Further, the pixel defining film may be patterned to form subpixel pits corresponding to the positions of the subpixels of the display substrate. The patterning process may be any suitable patterning process such as a photolithography process and a follow-up etching process. Dry etch or wet etch may be used for the etching process. The pixel defining layer 6 may include a pattern, e.g., arrangement of subpixel pits, corresponding to the subpixel arrangement of the display substrate.

The arrangement or position of the subpixel pits may correspond to the arrangement or positions of the subpixels. Each subpixel pit may correspond to one subpixel of a certain color. The subpixel pits may expose the surface of the anode layer 5 at the bottom of the subpixel pits. The sidewall of a subpixel pit may or may not be perpendicular to the surface of the anode layer 5. In one embodiment, the sidewall of a subpixel pit may form an acute angle with the surface of the anode layer 5 such that the cross-section of the subpixel pit may have a smaller width at the bottom and a greater width at the top.

In step S3, inkjet printing is applied to form light-emitting layers in the subpixel pits.

As shown in FIGS. 1 and 2, inkjet printing may be used to form light-emitting layers 7 in the subpixel pits. Nozzles of an inkjet printer may be aligned with the subpixel pits and may eject colorant ink of different colors into the corresponding subpixel pits. The colorant ink in each subpixel pit may partially fill up the subpixel pit and have contact with the sidewall of the subpixel pit and the anode layer 5. The colorant ink in each subpixel pit may undergo a drying process to evaporate a desired portion of solvent for forming the light-emitting layer 7 with sufficient mechanical strength and stiffness. The dried colorant ink in each subpixel pit may form a light-emitting layer 7. The light-emitting layer 7 may be able to emit light of a certain color, e.g., red, green, blue, in operation. The arrangement of light-emitting layer 7 may correspond to the arrangement of subpixels of the display substrate.

The colorant ink may contain any suitable organic or inorganic chemicals or solute capable of emitting light of a certain color, e.g., red, green, or blue. In one embodiment, the colorant ink may contain organic dyes. The light-emitting layer 7 may have sufficient stiffness and strength to sustain the subsequently formed subpixel barrier layer 8. The peripheral portion 10 of the light-emitting layer 7 may have a greater thickness than the center portion 14 of the light-emitting layer 7 after the drying process.

In step S4, a subpixel barrier film is formed on the light-emitting layer and the pixel defining layer and patterned to form the subpixel barrier layer, the subpixel barrier layer covering at least the peripheral portion of the light-emitting layer and exposing the center portion of the light-emitting layer.

As shown in FIGS. 1 and 2, a subpixel barrier film is formed on the light-emitting layer 7 and the pixel defining layer 6 and patterned to form the subpixel barrier layer 8. The subpixel barrier film may be formed by any suitable deposition methods such as vapor deposition. The patterning process may include a photolithography process and a follow-up etching process. In one embodiment, dry etch may be used as the etching process. The subpixel barrier layer 8 may at least cover the peripheral portion 10 of the light-emitting layer 7 and expose the center portion 14 of the light-emitting layer 7. The area of the center portion 14 may be sufficient for emitting light of a desired intensity or brightness.

The thickness of the subpixel barrier layer 8 may be adjusted according to the area of the peripheral portion 10 of the light-emitting layer 7. To substantially cover the peripheral portion 10, an peripheral portion 10 with a wider area may require a subpixel with a thicker insulating layer 8. An peripheral portion 10 with a narrower area may require a subpixel with a thinner insulating layer 8. The subpixel barrier layer 8 may be sufficiently thick to provide electrical insulation between the peripheral portion 10 of the light-emitting layer 7 so that the peripheral portion 10 does not emit light in operation. Meanwhile, the subpixel barrier layer 8 should not be overly thick to cause void between the light-emitting layer 7 and the cathode layer 9. The thickness of the subpixel barrier layer 8 should also be adjusted in a desired range so that sufficient area of the center portion 14 can be exposed for emitting light of a desired intensity. In one embodiment, the thickness of the subpixel barrier layer 8 may be the same as the thickness of the light-emitting layer 7. It should be noted that, the thickness of the subpixel barrier layer 8 in the disclosure may only be exemplary. The specific thickness of the subpixel barrier layer 8 may be determined or adjusted according to the area of the peripheral portion 10 of the light-emitting layer 7.

In step S5, a cathode layer is formed to cover the center portion of the light-emitting layer and to form contact with the center portion of the light-emitting layer.

As shown in FIGS. 1 and 2, a cathode layer 9 may be formed to cover the center portion 14 of the light-emitting layer 7 and the subpixel barrier layer 8 and form contact with the center portion 14 of the light-emitting layer 7. The subpixel barrier layer 8 may improve the adhesion between the pixel defining layer 6 and the cathode layer 9. The cathode layer 9 may be made of any suitable conductive material such as Al and/or MgAl. The cathode layer 9 may be formed by vapor deposition. For illustrative purposes, in one embodiment, the cathode layer 9 shown in FIG. 1 may cover the pixel defining layer 6, the light-emitting layer 7, and the subpixel barrier layer 8. In practice, the cathode layer 9 may only be required to contact the exposed portion of the light-emitting layer 7, i.e., the center portion 14 of the light-emitting layer 7. The specific coverage of the cathode layer 9 may adjusted according to different applications and should not be limited by the embodiments herein.

Thus, the light-emitting layer 7, the anode layer 5, and the cathode layer 9, may form a subpixel. The subpixel may emit light of a certain color, e.g., red, green, and blue, in operation. Subpixels emitting light of different colors may be arranged on the display substrate repeatedly to form pixels arrays for display images. By using the PLED structure and the disclosed fabrication method, light intensity of the subpixels may have improved uniformity and service time of the subpixels may be improved. The lighting quality of the subpixels may be improved.

Another aspect of the present disclosure provides a display substrate. The display substrate may incorporate a plurality of the PLED structures arranged repeatedly on the display substrate. One PLED structure may correspond to one subpixel. The plurality of the PLED structures may correspond to a plurality of subpixels.

Another aspect of the present disclosure provides a display apparatus. The display apparatus may incorporate the display substrate. The display apparatus according to the embodiments of the present disclosure can be used in any product with display functions such as a television, a liquid crystal display (LCD), an organic light-emitting diode (OLED) display, an electronic paper, a digital photo frame, a mobile phone, a tablet computer, and a navigation device.

It should be understood that the above embodiments disclosed herein are exemplary only and not limiting the scope of this disclosure. Without departing from the spirit and scope of this invention, other modifications, equivalents, or improvements to the disclosed embodiments are obvious to those skilled in the art and are intended to be encompassed within the scope of the present disclosure.

1-22. (canceled)

23. A polymer light-emitting diode (PLED) structure, comprising:
a substrate;
an anode layer on the substrate;
a pixel defining layer for defining a display region with a plurality of pixels;
a light-emitting layer in subpixels of each pixel for illuminating light of a color;
a subpixel barrier layer substantially positioned between the pixel defining layer and a cathode layer for covering a peripheral portion of the light-emitting layer and exposing a center portion of the light-emitting layer, an orthogonal projection of the subpixel barrier layer on the substrate overlapping with a portion of an orthogonal projection of the peripheral region of the light-emitting layer on the substrate; and
the cathode layer contacting the center portion of the light-emitting layer.

24. The PLED structure according to claim 23, wherein:
in operation, the subpixel barrier layer provides electrical insulation between the light-emitting layer and the cathode layer.

25. The PLED structure according to claim 24, wherein:
in operation, the subpixel barrier layer blocks light exiting from the peripheral portion of the light-emitting layer.

26. The PLED structure according to claim 23, wherein the peripheral portion of the light-emitting layer covered by the subpixel barrier layer has a thickness greater than a thickness of the center portion of the light-emitting layer for at least 3%.

27. The PLED structure according to claim 26, wherein the subpixel barrier layer contacts the sidewall of the subpixel pit and provides adhesion between the pixel defining layer and the cathode layer.

28. The PLED structure according to claim 23, wherein a thickness of the subpixel barrier layer is at least partially dependent on a width of the peripheral portion of the light-emitting layer.

29. The PLED structure according to claim 28, wherein the thickness of the subpixel barrier layer is substantially equal to a thickness of the light-emitting layer.

30. The PLED structure according to claim 23, wherein the subpixel barrier layer covers the peripheral portion of the light-emitting layer and the sidewall of the pixel defining layer.

31. The PLED structure according to claim 30, wherein the cathode layer covers the center portion of the light-emitting layer, the subpixel barrier layer, and the pixel defining layer.

32. The PLED structure according to claim 23, wherein the subpixel barrier layer is made of one or more of SiOₓ, SiNₓ and SiOₓN_{y}.

33. The PLED structure according to claim 23, further comprising:
a substrate with a thin-film transistor (TFT) array, and a planarization layer.

34. A method for forming a polymer light-emitting diode (PLED) structure for a display substrate, including:
providing a substrate with a thin-film transistor (TFT) array and an anode layer;
forming a pixel defining layer with subpixel pits corresponding to pixels of the display substrate, a bottom of each pit exposing a portion of the anode layer;
forming a light-emitting layer in each subpixel pit, each light-emitting layer filling up a portion of each pit, contacting a sidewall of the pit and an exposed portion of the anode layer;
forming a patterned subpixel barrier layer to cover at least a peripheral portion of the light-emitting layer and to expose a center portion of the light-emitting layer; and
forming a cathode layer to cover at least the center portion of the light-emitting layer and form contact with the center portion of the light-emitting layer.

35. The method according to claim 34, wherein in operation, the subpixel barrier layer provides electrical insulation between the peripheral portion of the light-emitting layer and the cathode layer so that the peripheral portion of the light-emitting layer does not emit light.

36. The method according to claim 35, wherein in operation, the subpixel barrier layer blocks light exiting from the peripheral portion of the light-emitting layer.

37. The method according to claim 35, wherein in operation, light emitted by the light-emitting layer has substantial uniformity.

38. The method according to claim 12, wherein a thickness of the subpixel barrier layer is at least partially dependent on a width of the peripheral portion of the light-emitting layer.

39. The method according to claim 34, wherein an orthogonal projection of the subpixel barrier layer on the substrate overlaps with a portion of an orthogonal projection of the peripheral portion of the light-emitting layer on the substrate.

40. The method according to claim 34, wherein the patterned subpixel barrier layer is formed by:
forming a subpixel barrier film to cover at least the light-emitting layer by vapor deposition; and
patterning the subpixel barrier film to form the subpixel barrier layer, the subpixel barrier layer covering at least the peripheral portion of the light-emitting layer and exposing the center portion of the light-emitting layer.

41. A display substrate, incorporating a plurality of the PLED structures according to claim 23.

42. A display apparatus, incorporating the display substrate of claim 41.
